(19) United States
(12) Patent Application Publication
(10) Pub. No.: US 2013/0269994 A1
(43) Pub. Date: Oct. 17, 2013

(54) PRINTED CIRCUIT BOARD WITH STRENGTHENED PAD

(71) Applicant: HAI-DONG TANG, Shenzhen City (CN)

(72) Inventor: HAI-DONG TANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/459,107

(22) Filed: Apr. 28, 2012

(30) Foreign Application Priority Data
Apr. 13, 2012 (CN) 201210108032.4

(51) Int. Cl. H05K 1/11

(52) U.S. Cl. 174/262

(57) ABSTRACT

A print circuit board (PCB) includes a first surface defining a number of first pads and a second surface defining a number of second pads. The number of the first pads is equal to the number of the second pads. Each first pad corresponds to one second pad and the first pad and the corresponding second pad form a pair of pads. Each pair of pads defines at least one via hole and each of the via hole connects the first pad and the second pad of each pair of pads.

### BACKGROUND

1. Technical Field

The present disclosure relates to a printed circuit board with strengthened pad.

2. Description of Related Art

Generally, electronic components are soldered to the printed circuit board (PCB) by pad. However, because the soldered electronic components protrude from the PCB, they are easily hit or pushed during transportation of the PCB, which may cause the pad to canted or pulled off from the PCB.

### BRIEF DESCRIPTION OF THE DRAWINGS

The components of the drawings are not necessarily drawn to scale, the emphasis instead being placed upon clearly illustrating the principles of the present disclosure. Moreover, in the drawings, like reference numerals designate corresponding parts throughout several views.

FIG. 1 is a schematic, top plan view of a printed circuit board in accordance with an exemplary embodiment.

FIG. 2 is a schematic, cross-sectional view of the printed circuit board of FIG. 1, taken along the line II-II of FIG. 1.

### DETAILED DESCRIPTION

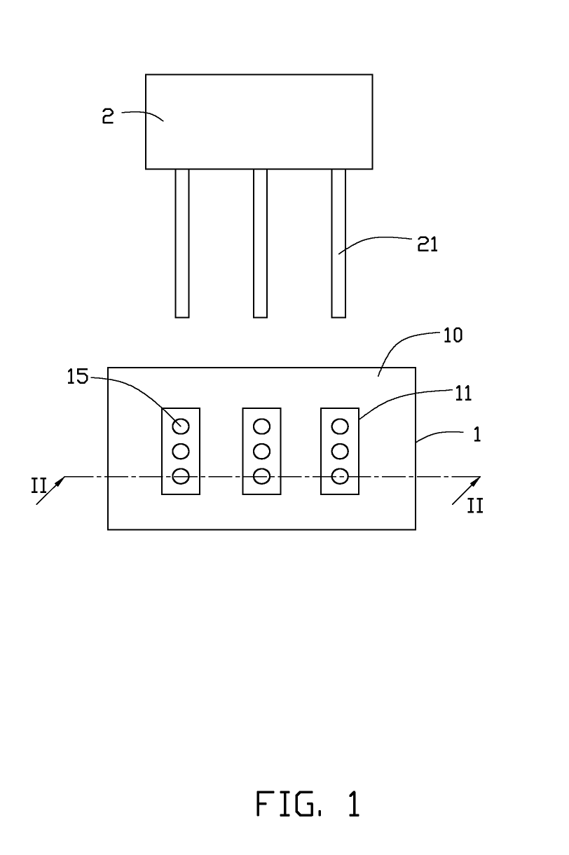

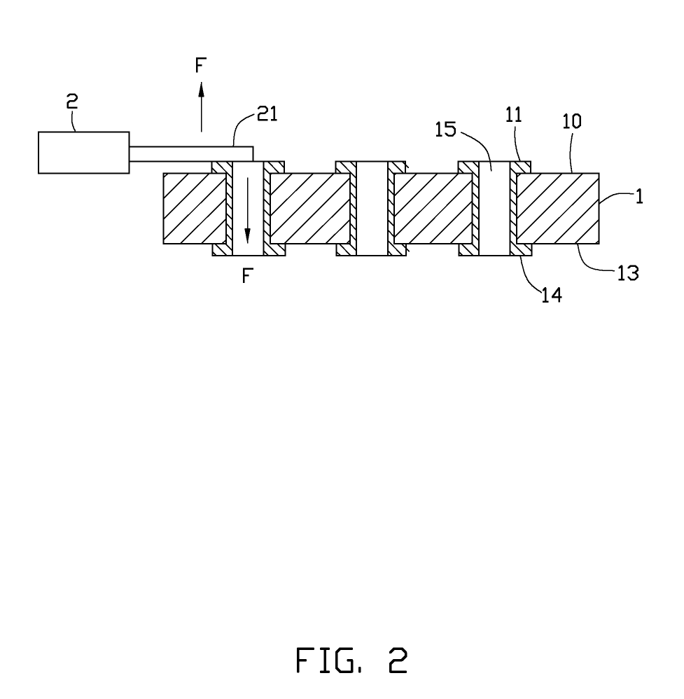

FIGS. 1 and 2 shows a printed circuit board (PCB) 1 includes a first surface 10 and a second surface 13. The first surface 10 defines a number of first pads 11. Pins 21 of an electronic component 2 are soldered to the first pads 11. The second surface 13 defines a number of second pads 14. The number of the first pads 11 is equal to the number of the second pads 14. Each first pad 11 corresponds to one second pad 14, and the first pad 11 and the corresponding second pad 14 form a pair of pads. Each pair of pads defines at least one via hole 15. The via hole 15 connects the first pad 11 to the second pad 14 of each pair of pads, thus engagement between the first pad 11 and the PCB 1 is strengthened. Thereby, when the first pad 11 is pulled by the electronic component 2, the second pad 14 generates a pulling force to the first pad 11 to make it so that the first pad 11 is not easily canted or pulled from the PCB 1. In the embodiment, the size of the first pad of each pair of pads is equal to the size of the second pad of each pair of pads and the position where the first pad of each pair of pads on the first surface corresponds to the position where the second pad of each pair of pads is on the second surface.

Although, the present disclosure has been specifically described on the basis of preferred embodiments, the disclosure is not to be construed as being limited thereto. Various changes or modifications may be made to the embodiment without departing from the scope and spirit of the disclosure.

What is claimed is:

1. A print circuit board (PCB) comprising:
a first surface defining a plurality of first pads;
a second surface defining a plurality of second pads;
wherein the number of the plurality of first pads is equal to the number of the plurality of second pads, each first pad corresponds to one second pad, and the first pad and the corresponding second pad form a pair of pads, each pair of pads defines at least one via hole, and each of the at least one via hole connects the first pad and the second pad of each pair of pads.

2. The PCB as described in claim 1, wherein the size of the first pad of each pair of pads is equal to the size of the second pad of each pair of pads and the position where the first pad of each pair of pads on the first surface corresponds to the position where the second pad of each pair of pads is on the second surface.
